(19) United States
(12) Patent Application Publication
(10) Pub. No.: US 2007/0126616 A1
(43) Pub. Date: Jun. 7, 2007

(54) Dynamically linearized digital-to-analog converter

(76) Inventors: Min Hyung Cho, Daejeon (KR); Chong Ki Kwon, Daejeon (KR); Jong Dae Kim, Daejeon (KR); Kwi Dong Kim, Daejeon (KR)

Correspondence Address: LADAS & PARRY LLP, 224 SOUTH MICHIGAN AVENUE, SUITE 1600, CHICAGO, IL, 60604, US

(21) Appl. No.: 11/591,740

(22) Filed: Nov. 2, 2006

(30) Foreign Application Priority Data
Dec. 7, 2005 (KR) 10-2005-0119106
May 23, 2006 (KR) 10-2006-0046037

(51) Int. Cl. H03M 1/66

(52) U.S. Cl. 341/144

(57) ABSTRACT

Provided is a digital-to-analog converter converting a digital signal into an analog signal. The digital-to-analog converter includes a decoder for selecting a current source from digital inputs, a current switch driver for driving a current switch of the current source, and a random selection switch disposed between the decoder and the current switch driver, and randomly resetting a connection relationship between outputs of the decoder and inputs of the current switch driver every clock. According to the present invention, the linearity of the digital-to-analog converter may be enhanced by changing the current source selected every clock signal to compensate for non-linearity of the digital-to-analog converter according to the spatial arrangement of the current sources.

### CROSS-REFERENCE TO RELATED APPLICATION

This application claims priority to and the benefit of Korean Patent Application Nos. 2005-119106, filed Dec. 7, 2005, and 2006-46037, filed May 23, 2006, the disclosures of which are incorporated herein by reference in their entirety.

### BACKGROUND

1. Field of the Invention

The present invention relates to a digital-to-analog converter whose non-linearity caused by spatial arrangement of current sources is compensated averagely.

2. Discussion of Related Art

In recent years, as digital signal processing techniques are developed, a signal processing method is widely used in which an analog signal is converted to a digital signal and processed and the digital signal is converted back to an analog signal. Also, an amount of data processed in wired/wireless communication systems increases. An amount of data to be converted into an analog signal also increases, and accordingly, a digital-to-analog converter having more excellent performance, and higher speed and resolution is required. A current driven digital-to-analog converter is known as the most suitable structure for high speed and resolution signal conversion.

Referring to FIG. 1, a conventional current driven digital-to-analog converter comprises a digital signal input buffer 1 for receiving an N-bit digital input signal, a decoder 2 selectively needed depending on the structure of the converter, a current switch driver 3 for output current driving, and a current source 4 including an array of unit current sources for generating output currents. Here, the current driven digital-to-analog converter may have one of a binary-weighted structure, a unary-weighted structure, a segmented structure, etc. according to the structure of the current source 4. The structure determines complexity of circuit and performance of each digital-to-analog converter.

A basic and important characteristic of the current driven digital-to-analog converter, static performance, is determined by arrangement of unit current sources in the current source. The reason why the static performance of the current driven digital-to-analog converter varies with the arrangement of the unit current sources in the current source is as follows. Even though the same elements are implemented within a chip, they may have different characteristics according to a spatial location due to fabrication processes and various factors. Therefore, although the current driven digital-to-analog converter is implemented using the same current sources, the static performance thereof may be limited due to misalignment on the characteristics of the current sources after the current driven digital-to-analog converter is fabricated.

The misalignment characteristics of the elements implemented in the chips have been analyzed through various studies, and various methods such as determination of a size of the current source to reduce the misalignment characteristics, a method of spatial arrangement of the current source, etc., have been suggested. The static performance of the digital-to-analog converters has been improved by the above methods.

Despite the application of the various methods to reduce the misalignment of the current sources, there exists a limit to improve the static performance. Currently, in addition to the static performance, improvement of dynamic performance of the digital-to-analog converter is getting more important due to the development of wideband signal processing systems.

### SUMMARY OF THE INVENTION

The present invention is directed to a method of dynamically compensating for misalignment between devices at a time when the digital-to-analog converter operates, and a digital-to-analog converter having a new structure whose dynamic linearity is enhanced by the method.

One aspect of the present invention is to provide a digital-to-analog converter including: a decoder for selecting a current source from digital inputs, a current switch driver for driving a current switch of the current source; and a random selection switch located between the decoder and the current switch driver for randomly resetting a connection relationship between outputs of the decoder and inputs of the current switch driver every clock.

In one embodiment, the random selection switch randomly selects one signal group from a plurality of signal groups output from the decoder as an input of the current switch driver, wherein said plurality of signal groups correspond plurality of unit current source groups constituting the current source.

In another embodiment, the random selection switch randomly selects one signal from each group of a plurality of signal groups output from the decoder as an input of the current switch driver, wherein said plurality of signal groups correspond a plurality of unit current source groups constituting the current source.

Another aspect of the present invention is to provide a digital-to-analog converter including: a random selection switch for randomly resetting outputs of the unit element selecting outputs from digital inputs according to a reference signal, i.e., a clock signal. In this case, the digital-to-analog converter may include all types of digital-to-analog converters other than a current driven digital-to-analog converter.

According to the present invention, it is possible to provide a digital-to-analog converter having enhanced dynamic linearity by randomly changing the unit current sources selected every clock signal at a time when the digital-to-analog converter operates, thereby dynamically compensating for static performance determined by the spatial arrangement of the unit current sources in the current driven digital-to-analog converter, and the misalignment characteristics of the unit current sources caused by the spatial arrangement.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIG. 1 is a block diagram schematically illustrating a structure of a current driven digital-to-analog converter according to an exemplary embodiment of the present invention;

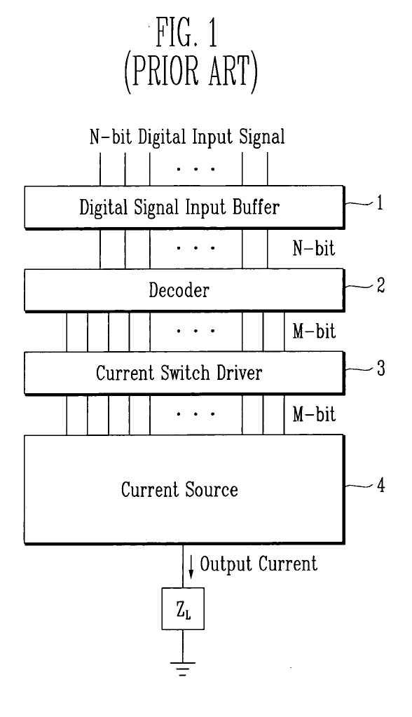

FIG. 2 is a block diagram illustrating a basic structure of a dynamically linearized digital-to-analog converter having a new structure according to an exemplary embodiment of the present invention;

FIG. 3 is a block diagram illustrating a structure of the digital-to-analog converter obtained by dividing unit current sources into a plurality of groups, and applying a dynamic linearization method to each unit current source group according to an exemplary embodiment of the present invention;

FIG. 4 is a block diagram illustrating a structure of the digital-to-analog converter obtained by dividing unit current sources into a plurality of groups, and applying a dynamic linearization method to each group according to an exemplary embodiment of the present invention; and

FIG. 5 is a block diagram illustrating a segmented structure of a digital-to-analog converter to which a dynamic linearization method is applied according to an exemplary embodiment of the present invention.

### DETAILED DESCRIPTION OF PREFERRED EMBODIMENTS

Hereinafter, an exemplary embodiment of the present invention will be described in detail. However, the present invention is not limited to the embodiments disclosed below, but can be implemented in various types. Therefore, the present embodiment is provided for complete disclosure of the present invention and to fully inform the scope of the present invention to those ordinarily skilled in the art.

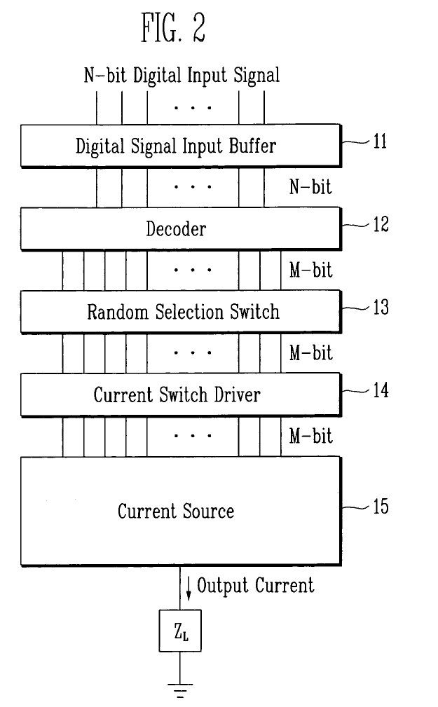

FIG. 2 is a block diagram illustrating a basic structure of a dynamically linearized digital-to-analog converter having a new structure according to an exemplary embodiment of the present invention.

Referring to FIG. 2, the current driven digital-to-analog converter according to the present invention may further comprise a random selection switch 13 block disposed between a decoder 12 and a current switch driver 14.

The decoder 12 receives N-bit digital input signals, and selects a current source from the received digital input signals. At this time, a digital signal input buffer 11 for efficiently receiving the N-bit digital input signals may be disposed in a previous stage of the decoder 12.

The current switch driver 14 receives the digital input signals from the decoder 12, and drives a current switch of the current source.

The random selection switch 13 is located between the decoder 12 and the current switch driver 14 and randomly resets outputs of the decoder 12 and inputs of the current switch driver 14 every clock. The random selection switch 13 may be implemented as a random selection switch array.

The current driven digital-to-analog converter newly provided by the present invention has a random selection switch array block disposed between blocks of the decoder and the current switch driver, which randomly changes a connection between the outputs of the decoder and the inputs of the current switch driver every clock. The unit current sources selected every clock are configured to be randomly selected so that each unit current source has an equal chance to be selected, which results in removal of misalignment effects due to the spatial arrangement of each unit current source, and improvement of dynamic linearity of the digital-to-analog converter.

As described above, a unit current source selected for the specific digital input is not fixed but changed every instant, and this change can be realized in a direction for compensating for the non-linearity between the unit current sources. The digital-to-analog converter can be implemented with high linearity by compensating for the non-linearity between the unit current sources during the operation of the digital-to-analog converter.

Meanwhile, the additional random selection switch array in the digital-to-analog converter according to an exemplary embodiment of the present invention has an M number of inputs and an M number of outputs, in which the number of the inputs and outputs of this block may increase depending on the structure of the digital-to-analog converter, which results in a complex configuration of randomly changing the connection relationship between the input signal and the output signal with respect to each input and output signals.

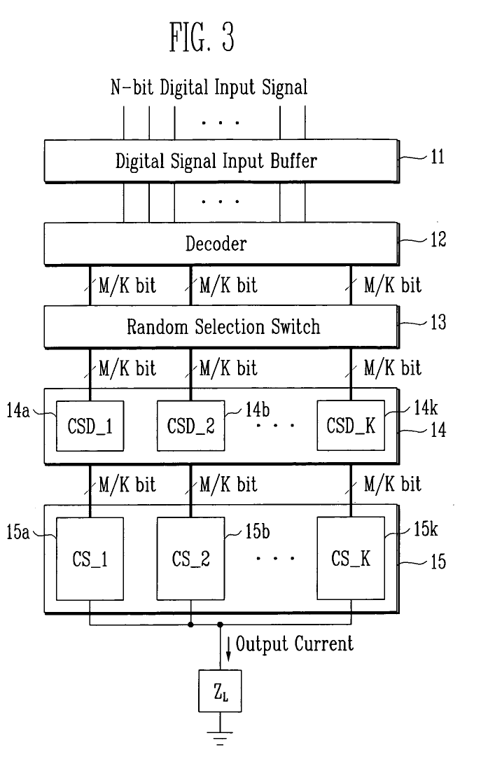

Three embodiments of the present invention in which a connection relationship between the input and output signals is changed with respect to each input and output will be described with reference to FIGS. 3 to 5.

FIG. 3 is a block diagram illustrating a structure of the digital-to-analog converter obtained by dividing unit current sources into a plurality of groups and applying a dynamic linear method to each current source group according to an exemplary embodiment of the present invention.

Referring to FIG. 3, the digital-to-analog converter according to an exemplary embodiment of the present invention comprises a decoder 12, a random selection switch 13, a current switch driver 14 having a plurality of unit current switch drivers CSD1 to CSD_K, and a current source 15 having a plurality of unit current sources CS_1 to CS_K in the same sizes.

The digital-to-analog converter according to an exemplary embodiment of the present invention has a structure in which unit current sources in an array are divided into several unit current source groups to compensate for each characteristic of the unit current sources, the unit current source groups are randomly selected, and misalignment effects caused by the spatial arrangement between the unit current source groups are dynamically removed.

With respect to the above-described structure, operations of the digital-to-analog converter according to an exemplary embodiment of the present invention will be described. The input N-bit digital input signals are transmitted to the decoder 12 through a digital signal input buffer 11, the decoder 12 selects a unit current source from the digital signal inputs, and the outputs of the decoder 12 are transmitted to the current switch driver 14. At this time, after the plurality of M/K bit signals grouping the unit current sources into the plurality groups are randomly reset through the random selection switch 13, the outputs of the decoder 12 are transmitted to the corresponding unit current switch drivers 14A to 14K in the current switch driver 14, and the unit current switch drivers drive current switches of the corresponding unit current sources based on the transmitted signals. The digital-to-analog converter outputs current data whose dynamic linearity is enhanced according to the above described operations.

According to the described configuration, the misalignment caused by the spatial arrangement of the unit current sources in the conventional digital-to-analog converter may be compensated by randomly connecting each unit current source grouped into one group according to each clock signal for the operation of the converter at the random selection switch 13. In other words, the misalignment between the unit current source groups may be minimized.

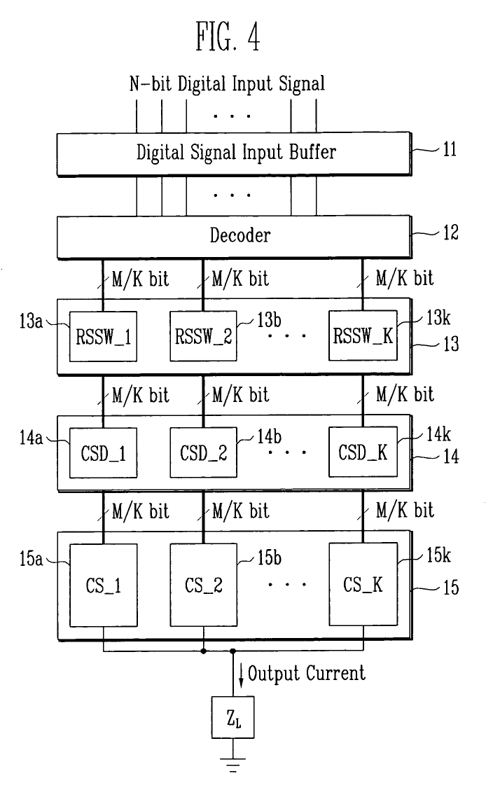

FIG. 4 is a block diagram illustrating a structure of the digital-to-analog converter obtained by dividing unit current sources into a plurality of groups, and applying a dynamic linearization method to each group according to an exemplary embodiment of the present invention.

Referring to FIG. 4, the digital-to-analog converter according to an exemplary embodiment of the present invention comprises a decoder 12, a random selection switch 13 having a plurality of unit random selection switches RSSW_1 to RSSW_K, a current switch driver 14 having a plurality of unit current switch drivers CSD1 to CSD_K, and a current source 15 having a plurality of unit current sources CS_1 to CS_K.

The digital-to-analog converter according to an exemplary embodiment of the present invention has a structure in which unit current sources are divided into several groups, and in each unit current source group, the misalignment effects caused by spatial arrangement of the individual unit current sources are removed. This structure may be more apparently understood by the following description of operations.

The operations of the digital-to-analog converter according to an exemplary embodiment of the present invention will be described. N-bit digital input signal inputs to the digital-to-analog converter is transmitted to the decoder 12 through the digital signal input buffer 11, the decoder 12 selects a unit current source from the input digital signals, and outputs of the decoder 12 are transmitted to the current switch driver 14. At this time, the outputs of the decoder 12 are transmitted to the unit random selection switches 13A to 13K in the random selection switch 13, all of which correspond to the plurality of M/K bit signals that group the unit current sources into the plurality of groups. The unit random selection switches 13A to 13K randomly reset the unit current sources in each group and then transmit the unit current sources to the plurality of corresponding unit current switch drivers 14A to 14K in the current switch driver 14. The unit current switch drivers 14A to 14K drive current switches of the corresponding unit current sources 15A to 15K based on the transmitted signals. According to the described operations, the digital-to-analog converter outputs current data whose dynamic linearity is improved.

According to the above-described configuration, the misalignment caused by the spatial arrangement between the unit current sources in the unit current source groups is compensated, which results in the minimization of the misalignment in the unit current source groups.

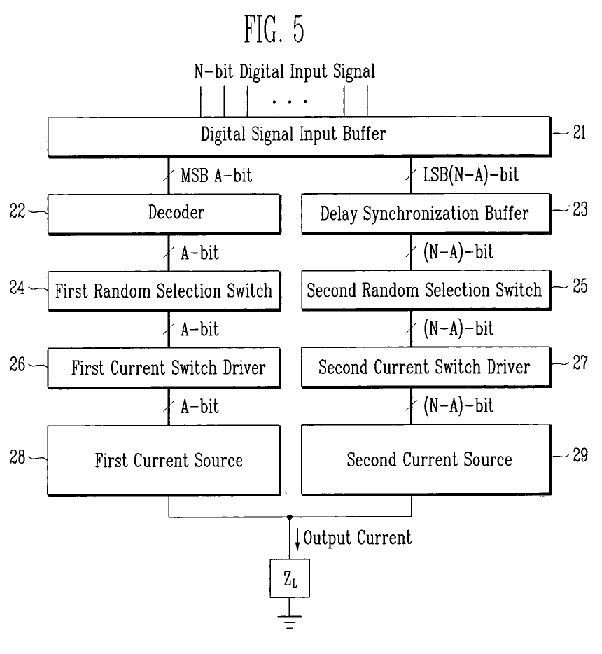

The provided method that dynamically compensates for the limited static performance of the digital-to-analog converter, thereby enhancing the linearity of the digital-to-analog converter may be applied to the conventional digital-to-analog converters. For example, a segmented structure of the current driven digital-to-analog converter to which the dynamic linearization method is applied is illustrated in FIG. 5.

FIG. 5 is a block diagram illustrating a segmented structure of a digital-to-analog converter to which a dynamic linearization method is applied according to an exemplary embodiment of the present invention.

Referring to FIG. 5, the digital-to-analog converter according to an exemplary embodiment of the present invention comprises a digital signal input buffer 21 for receiving N-bit digital input signals and outputting the input signals as two groups of the Most Significant Bit (MSB) A-bit and the Least Significant Bit (LSB) (N-A)-bit, a decoder 22 for selecting a current source from the digital signal of the MSB A-bit, a delay synchronization buffer 23 for selecting a current source from the digital signal of the LSB (N-A) bit, a first random selection switch 24 for randomly resetting the output of the decoder 22, a second random selection switch 25 for randomly resetting the output of the delay synchronization buffer 23, a first current switch driver 26 for driving a current switch of the first current source 28 previously selected by receiving the output of the decoder 22 randomly reset by the first random selection switch 24, and a second current switch driver 27 for driving a current switch of the second current source previously selected by receiving the output of the delay synchronization buffer 23 randomly reset by the second random selection switch 25.

The digital-to-analog converter according to an exemplary embodiment of the present invention is characterized in that the first and second random selection switches 26 and 27 are provided for dynamic linearization of the MSB and LSB of the input N-bit digital input signal, and the random selection switches 26 and 27 can be configured by selecting and using one of the proposed methods based on the structure of the MSB and the LSB parts.

As described above, a digital-to-analog converter having a new structure according to the dynamic linearization method of the present invention is provided. A digital-to-analog converter, particularly, a current driven digital-to-analog converter can be easily implemented with a higher dynamic linearity than that of a conventional current driven digital-to-analog converter by dynamically compensating for linearity deterioration caused by the misalignment due to spatial arrangement of the unit current sources.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A digital-to-analog converter comprising:
a decoder for selecting a current source from digital inputs;
a current switch driver for driving a current switch of the current source; and
a random selection switch located between the decoder and the current switch driver, and randomly resetting a connection relationship between outputs of the decoder and inputs of the current switch driver every clock.

2. The digital-to-analog converter of claim 1, wherein the random selection switch randomly selects one signal group from a plurality of signal groups output from the decoder as an input of the current switch driver, said plurality of signal groups corresponding a plurality of unit current source groups constituting the current source.

3. The digital-to-analog converter of claim 1, wherein the random selection switch randomly selects one signal from each group of a plurality of signal groups output from the decoder as an input of the current switch driver, said plurality of signal groups corresponding a plurality of unit current source groups constituting the current source.

4. A digital-to-analog converter, comprising:
a unit element for selecting outputs from digital inputs; and
a random selection switch for resetting the outputs of the unit element during the operation of the converter according to a clock signal.

5. The digital-to-analog converter of claim 4, further comprising a current switch driver for driving a current switch of a current source by receiving the outputs of the unit element, wherein the current source has a segmented structure.
